(19) United States
(12) Patent Application Publication
(10) Pub. No.: US 2025/0337420 A1
(43) Pub. Date: Oct. 30, 2025

(54) RESISTOR-ASSISTED SUPPLY SENSITIVITY IMPROVED RING OSCILLATOR FOR WIRELINE AND WIRELESS APPLICATIONS

(71) Applicant: INDIAN INSTITUTE OF TECHNOLOGY ROPAR, Rupnagar (IN)

(72) Inventors: Mahendra SAKARE, Rupnagar (IN); Mayank Kumar SINGH, Rupnagar (IN); Hirensh MEHRA, Rupnagar (IN); Rajasekhar NAGULAPALLI, Oxford (GB)

(73) Assignee: INDIAN INSTITUTE OF TECHNOLOGY ROPAR, Rupnagar (IN)

(21) Appl. No.: 18/829,110

(22) Filed: Sep. 9, 2024

(30) Foreign Application Priority Data
Apr. 25, 2024 (IN) 202411032692

(51) Int. Cl. H03L 7/099; H03K 3/03; H03L 7/081

(52) U.S. Cl. CPC H03L 7/0995; H03K 3/0315; H03L 7/081

(57) ABSTRACT

Disclosed is a Phase-Locked Loop (PLL) with an improved ring oscillator 200. The Phase-Locked Loop (PLL) comprises a delay cell 100. The delay cell 100 may further comprise a main cell 102. Further a delay compensation circuitry 104, is integrally connected with the main cell 102. The Phase-Locked Loop (PLL) comprises a ring oscillator 200 connected with the delay circuit 100. Further the ring oscillator 200 is configured to be supply sensitive and assisted with a resistor. The ring oscillator 200 is connected to the delay cell 102 via the delay compensation circuitry 104. Further the ring oscillator 200 comprises a plurality of stages 202, and each stage from the plurality of stages 202 is cross-coupled with a next or an adjacent stage from the plurality of stages 202.

### CROSS-REFERENCE TO RELATED APPLICATIONS AND PRIORITY

The present application claim priority from Indian Patent Application number 202411032692 submitted on 25 Apr. 2024.

### TECHNICAL FIELD

The present disclosure relates to the field of electronics and communication engineering, and more particularly to an improved supply-sensitive ring oscillator to integrate fractional-N phase-locked loops (PLLs) or wireline SERDES receivers.

### BACKGROUND

In both wireline and wireless communication systems, precise and stable clock signals are crucial for accurate data sampling. The data sampling is particularly critical within the gigahertz (GHz) frequency range of 1 to 12.5 GHz. For ensuring reliable operation within this frequency range demands precise timing to mitigate signal jitter, that can significantly degrade performance and accuracy. However, obtaining high-frequency clock signals directly from available reference frequencies (0.01 to 156 MHz) is challenging.

To address this disparity in frequencies and bridge the frequency gap, synthesizers are commonly deployed. The synthesizers are configured to utilize phase-locked loop (PLL) to generate higher-frequency clock signals based on lower-frequency references. The PLL may be further configured to operates by comparing the phase of a feedback signal derived from the output clock to that of a reference signal, thereby adjusting the output frequency to maintain synchronization, i.e., to compare the phase of a feedback signal derived from the output clock to a reference signal, adjusting the output frequency to ensure synchronization and generate higher-frequency clock signals from lower-frequency references.

The integer-N PLL architecture is frequently utilized for its simplicity and effectiveness. In this architecture, the PLL generates output frequencies by digitally dividing the reference frequency using integer values, thereby enabling frequency multiplication. However, challenges persist in optimizing the performance of integer-N PLLs for high-frequency applications, particularly concerning phase noise, jitter, and power consumption.

Further to enhance the performance and reliability of wireline and wireless receivers operating within the GHz frequency range of 1 to 12.5 GHZ, hinges on addressing these challenges. Improving the PLL design hold the potential to advance clock generation, ultimately enabling improved data sampling precision, reduced jitter, and enhanced system performance. Therefore, there is a need in the art to optimize PLL-based synthesizers for high-frequency applications, ensuring the provision of stable and low-jitter clock signals vital for data sampling in modern communication systems.

Hence to overcome the aforesaid drawbacks a resistor-assisted supply sensitivity improved ring oscillator with improved supply sensitivity is required.

### OBJECTS

Main object of the present disclosure is to provide improved supply sensitivity to mitigate supply-induced spurs in the frequency domain and deterministic jitter in the time domain.

Another object of the present disclosure is to provide improved clock quality without necessitating additional silicon area or increasing power consumption.

### SUMMARY

Before the present system is described, it is to be understood that this application is not limited to the particular machine, device, or system, as there can be multiple possible embodiments that are not expressly illustrated in the present disclosures. It is also to be understood that the terminology used in the description is for the purpose of describing the particular versions or embodiments only, and is not intended to limit the scope of the present application. This summary is provided to introduce aspects related to a resistive assisted ring oscillator with improved supply sensitivity, and the aspects are further elaborated below in the detailed description. This summary is not intended to identify essential features of the proposed subject matter nor is it intended for use in determining or limiting the scope of the proposed subject matter.

In an aspect of the present disclosure, a Phase-Locked Loop (PLL) with an improved ring oscillator 200 is disclosed. The Phase-Locked Loop (PLL) comprises a delay cell 100. The delay cell 100 may further comprise a main cell 102. Further a delay compensation circuitry 104, is integrally connected with the main cell 102. The Phase-Locked Loop (PLL) comprises a ring oscillator 200 connected with the delay circuit 100. Further the ring oscillator 200 is configured to be supply sensitive and assisted with a resistor. The ring oscillator 200 is connected to the delay cell 102 via the delay compensation circuitry 104. Further the ring oscillator 200 comprises a plurality of stages 202, and each stage from the plurality of stages 202 is cross-coupled with a next or an adjacent stage from the plurality of stages 202.

In an embodiment, the present invention discloses that the main cell 102 comprises a plurality of NOT Gate (Inverter).

In an embodiment, the present invention discloses that the compensation circuitry 104 comprises at least two transmission gate (T-gate) 106a, 106b.

In an embodiment, the present invention discloses that at least two transmission gate (T-gate) 106 are configured to have unequal strengths for P and N transistors.

In an embodiment, the present invention discloses that the compensation circuitry 104 having the at least two transmission gate (T-gate) 106 is configured to adjust the size of the T-gate 106 through a 4-bit code (F_con<3:0>).

In an embodiment, the present invention discloses that the compensation circuitry 104 comprises at least two poly resistor 108, wherein each of the poly resistor 108 from the at least two poly resistor 108 is connected to each of the transmission gate (T-gate) 106a, 106b from the at least two transmission gate (T-gate) 106.

In an embodiment, the present invention discloses that at least two poly resistor 108 have a fixed resistance value of R=3.4 kΩ.

In an embodiment, the present invention discloses that the compensation circuitry 104 is provided within the delay cell 100 and is positioned between a first stage 202-1 and a last stage 202-2 from the plurality of stages 202.

In an embodiment, the present invention discloses that a first input 202a at the first stage 202-1 is connected with a first transmission gate (T-gate) 106a and a second input 202b at the first stage 202-1 is connected with a second transmission gate (T-gate) 106b.

In an embodiment, the present invention discloses that first output 202c at the last stage 202-2 is connected with the first transmission gate (T-gate) 106a and a second output 202d provided at the last stage 202-2 is connected with the second transmission gate (T-gate) 106b.

### BRIEF DESCRIPTION OF THE DRAWINGS

The foregoing summary, as well as the following detailed description of embodiments, is better understood when read in conjunction with the appended drawings. For the purpose of illustrating the disclosure, there is shown in the present document example constructions of the disclosure, however, the disclosure is not limited to the specific methods and device disclosed in the document and the drawing. The detailed description is described with reference to the following accompanying figures.

FIG. 1, illustrates a conventional phase-locked loop (PLL) architecture in accordance with a prior art.

FIG. 2, illustrates a conventional phase-locked loop (PLL) in accordance with a prior art.

FIG. 3, illustrates a conventional 4-stage ring oscillator in accordance with a prior art.

FIG. 4, illustrates a delay cell in accordance with an exemplary embodiment.

FIG. 5, illustrates the waveforms of each stage of the proposed differential delay cell.

FIG. 6, illustrates a 4-stage ring oscillator in accordance with an exemplary embodiment of the present disclosure.

FIG. 7, illustrates a simulation comparison of supply sensitivity in accordance with an exemplary embodiment.

FIG. 8, illustrates a frequency sensitivity for ring oscillator 200 in accordance with the exemplary embodiment.

The figures depict various embodiments of the present disclosure for purposes of illustration only. One skilled in the art will readily recognize from the following discussion that alternative embodiments of the structures illustrated herein may be employed without departing from the principles of the disclosure described herein

### DETAILED DESCRIPTION OF THE INVENTION

Some embodiments of this disclosure, illustrating all its features, will now be discussed in detail. The words “comprising”, “having”, and “including,” and other forms thereof, are intended to be equivalent in meaning and be open ended in that an item or items following any one of these words is not meant to be an exhaustive listing of such item or items, or meant to be limited to only the listed item or items. It must also be noted that as used herein and in the appended claims, the singular forms “a,” “an,” and “the” include plural references unless the context clearly dictates otherwise. Although any devices and methods similar or equivalent to those described herein can be used in the practice or testing of embodiments of the present disclosure, the exemplary, devices and methods are now described. The disclosed embodiments are merely exemplary of the disclosure, which may be embodied in various forms.

Various modifications to the embodiment will be readily apparent to those skilled in the art and the generic principles herein may be applied to other embodiments. However, one of ordinary skill in the art will readily recognize that the present disclosure is not intended to be limited to the embodiments illustrated, but is to be accorded the widest scope consistent with the principles and features described herein.

Following is a list of elements and reference numerals used to explain various embodiments of the present subject matter.

| Reference Numeral | Element Description |
|---|---|
| 100 | Delay cell |
| 102 | Main cell |
| 104 | Delay compensation circuitry |
| 106a, 106b | Transmission gate (T-gate) |
| 108 | Poly resistor |
| 200 | Ring oscillator |
| 202 | Plurality of stages |
| 202-1 | First stage |
| 202-2 | Last stage |
| 202a | First input |
| 202b | Second input |
| 202c | First output |
| 202d | Second output |

The present exemplary discloses an improved supply-sensitive ring oscillator integrated with an improved delay cell. The delay cell integrated with supply sensitive ring may be configured to further seamlessly integrate with Fractional-N Phase-Locked Loops (PLLs) or Wireline SERDES (Serializer/Deserializer) receivers. The PLLs serve as indispensable elements within a clocked system. The PLLs may be configured to generate high-frequency, low-jitter clocks derived from low-frequency reference signals.

The improved supply-sensitive ring oscillator may serve as the core component of the PLL system, providing a stable and precise clock signal. The present exemplary embodiment, minimize supply sensitivity while upholding high performance standards. Further the improved ring oscillator as disclosed in the exemplary embodiment, is resilient to supply noise. The improved ring oscillator may be configured to engage with a sophisticated compensation mechanism. Further, the improved oscillator is configured to adeptly mitigates the adverse effects of supply variations on its output frequency.

In accordance with an exemplary embodiment, a delay cell for Phase-Locked Loop (PLL) is disclosed. The delay cell, may be integrated within PLLs, using a compensation circuitry to effectively mitigate this supply sensitivity while upholding stability and performance requirements.

The delay cell may comprise a main cell, a cross-coupled pair, and an integrated delay compensation circuitry. The compensation circuitry is configured to counteract the detrimental effects of supply voltage variations on NMOS resistance. Further the compensation circuitry comprises a transmission gate (T-gate) with unequal strengths for P and N transistors, a poly resistor, and a controllable T-gate strength calibrated during the power-up state of the PLL. The integrated approach ensures robust compensation mechanisms within the delay cell, enhancing its ability to withstand supply fluctuations without compromising performance.

The synergy between the T-gate and poly resistor is pivotal in achieving effective compensation for NMOS resistance sensitivity. Further the T-gate strength, may be adjustable through a 4-bit code (F_con<3:0>), and offers flexibility in fine-tuning the compensation mechanism to suit specific requirements. Additionally, the poly resistor, fixed at a value of R=3.4 kΩ, is meticulously chosen based on comprehensive simulation studies accounting for layout parasitic and performance optimization considerations.

Through rigorous simulation analyses, the optimal values for the T-gate strength and poly resistor are determined, considering factors such as process variations, temperature effects, and layout parasitics. This meticulous optimization process ensures that the proposed delay cell achieves enhanced performance while effectively mitigating supply sensitivity, thereby preserving stability across varying supply voltages.

To validate the effectiveness of the proposed delay cell in practical applications, a 4-stage ring oscillator is implemented, showcasing its performance in real-world scenarios. Additional pins are incorporated for controlling the T-gate strength, enabling fine-tuning of the compensation mechanism to accommodate diverse operating conditions and requirements.

Supply sensitivity, a critical parameter in PLL design typically measured in MHz/mV, is meticulously addressed through the carefully crafted compensation circuitry within the proposed delay cell. By optimizing supply sensitivity and ensuring robust compensation mechanisms, this innovation significantly enhances PLL stability and reliability, thereby advancing clock generation in wireline and wireless communication systems to unprecedented levels of efficiency and robustness.

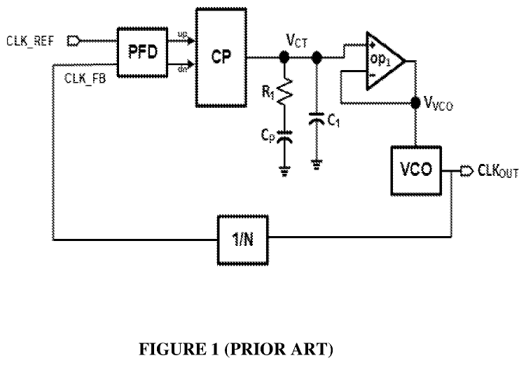

Referring to FIG. 1, illustrates a prior art comprising a conventional phase-locked loop (PLL) architecture. The conventional phase-locked loop (PLL) architectures may comprise a plurality of components configured to play integral roles in generating stable and precise high-frequency clock signals. The plurality of components includes a Phase Frequency Detector (PFD), a Charge Pump (CP), a Loop Filter, a Voltage-Controlled Oscillator (VCO), and a frequency divider.

The Phase Frequency Detector (PFD) is configured to compare a phase of a feedback signal derived from an output clock with a reference signal. Further the phase frequency (PFD) is configured to generate up/down signals that drive the Charge Pump (CP). The Charge Pump (CP) in turn produces a pulse-width modulated current. The width of the pulse-width modulated current is directly proportional to the input phase error, thereby facilitating accurate phase correction.

The generated current from the Charge Pump (CP) is further filtered through the Loop Filter. The Loop Filter is further configured to ensure smooth and stable voltage control. The anticipated voltage for the stable voltage control is generated on a node Vct. Further the node Vct is configured to buffer a unity gain operational amplifier (op1). The buffer stage enables to maintain signal integrity, in the presence of noise originating from both the Charge Pump (CP) and the power supply. The small signal bandwidth of the buffer is critical to effectively suppress noise, ensuring reliable PLL operation.

In the conventional phase-locked loop (PLL), the charge pump (CP) and frequency divider are configured to operate on a regulated power supply to reduce power supply-induced noise and continue stable operation.

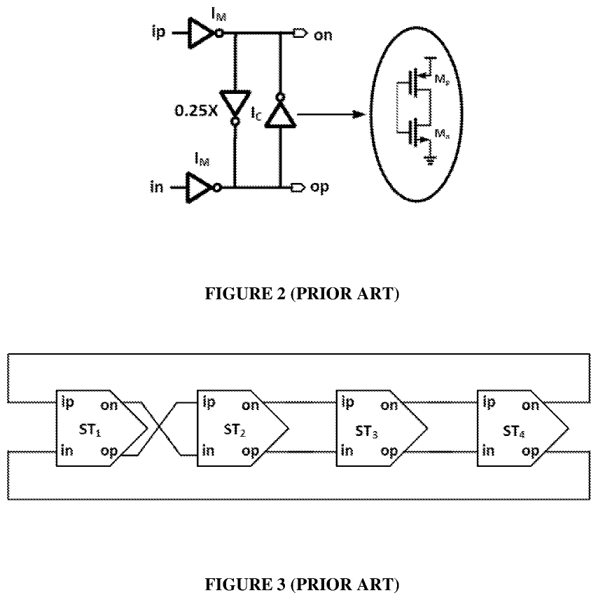

A prior art comprising a conventional delay cell as illustrated in FIG. 2, may comprise a main delay cell (IM) and a cross-coupled delay cell (CCDC). The main delay cell (IM) is configured to introduce a required or preset delay in an input clock signal. Further the cross-coupled delay cell (CCDC) is configured to verify the on/op signals exhibit complementarity or differential behavior.

The conventional delay cell is configured to maintain a delicate balance between the main delay cell (IM) and a plurality of cross-coupling stages within the delay cell (IM). The plurality of cross-coupling stages may be marginally weaker than the main inverter to prevent the output from latching to either ‘high’ or ‘low’ states. Typically, a ratio of 1:4 is maintained between the main and cross-coupling stages to achieve this balance effectively.

The plurality of cross-coupled delay cell (CCDC) stages, at each stage provides more than a 90-degree phase shift across the frequency spectrum. The design facilitates sustained oscillations across different Process, Voltage, and Temperature (PVT) corners, ensuring reliable operation of the delay cell under varying operating conditions.

Referring to FIG. 3, illustrates a prior art comprising a conventional 4-stage ring oscillator. The conventional 4-stage ring oscillator comprises a cross-connection at the interface of a ST1 stage, and a ST2 stage. The conventional 4-stage ring oscillator is deployed without frequency calibration, and configured to leverage a high KVCO (Voltage-Controlled Oscillator Gain). Leveraging the high KVCO enables a significant frequency range, effectively compensating for Process, Voltage, and Temperature (PVT) variations, providing a notable advantage over an inductance capacitance (LC) voltage-controlled oscillator (VCO). However, the conventional 4-stage ring oscillator are susceptible to voltage variations, resulting in increased deterministic jitter.

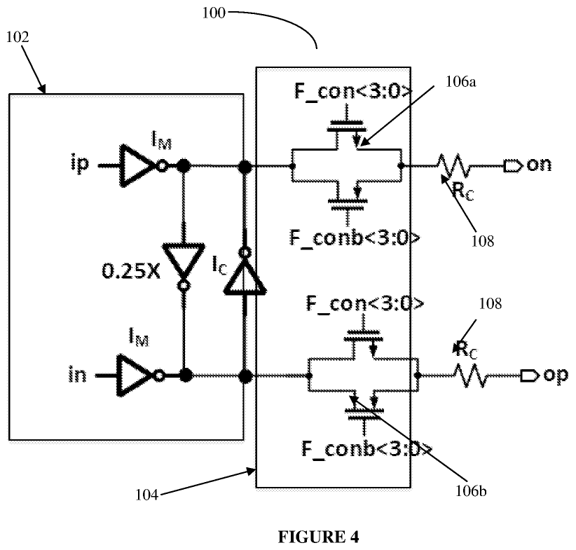

FIG. 4, illustrates a delay cell in accordance with an exemplary embodiment. A resistor-assisted supply sensitivity improved ring oscillator for wireline and wireless applications may be comprise a delay cell 100. The delay 100 cell may be configured to mitigate supply sensitivity issues originating from the high sensitivity of a N-channel metal-oxide semiconductor (NMOS) resistance to a supply voltage, primarily due to elevated NMOS mobility. The delay cell 100 may comprise a main cell 102. The main cell 102 may further comprise a plurality of NOT Gate (Inverter). Further the main cell 102 may be integrated with a cross-coupled pair along with a delay compensation circuitry 104. Further the delay compensation circuitry 104 may be integrated with the main cell 102.

The compensation circuitry 104 may comprise at least two transmission gate (T-gate) 106a and 106b, together referred as 106. Further the at least two transmission gate (T-gate) 106 may be configured to have unequal strengths for P and N transistors. The compensation circuitry 104 may further comprise at least two poly resistor 108. In accordance with the aspect, each of the poly resistor 108 from the at least two poly resistor 108 may be connected to each of the transmission gate (T-gate) 106 from the at least two transmission gate (T-gate) 106.

In accordance with the exemplary embodiment, the at least two transmission gate (T-gate) 106 may be further configured to control strength of the T-gate. Further the at least two transmission gate (T-gate) 106 may be calibrated during a power-up state of a fractional-N phase-locked loops (PLLs). The main cell 102 integrated with the delay compensation circuitry 104 in combination are configured to counteract the supply sensitivity issue and provide stable and reliable operation of the delay cell 100 across varying voltage conditions.

The compensation circuitry 104 having the at least two transmission gate (T-gate) 106 may be configured to adjust the size of the T-gate 106 through a 4-bit code (F_con<3:0>). Further the compensation circuitry 104 is configured to effectively counteract the sensitivity of NMOS resistance to supply voltage variations. Further, the at least two poly resistor 108 with a fixed resistance value of R=3.4 kΩ is integrated into the circuit to further enhance compensation.

In accordance with the exemplary embodiment, the improved delay cell 100 operates efficiently and reliably under varying operating conditions, including changes in the supply voltage. The improved delay cell 100 is further configured to effectively address supply sensitivity thereby improve performance of the PLLs requiring precise timing.

FIG. 5 illustrates the waveforms of each stage of the proposed delay cell (100). The complementary input signal (I_{P}) and (I_{N}) as shown in FIG. 4 has a 180-degree phase shift). The Main cell (102) provides the necessary delay to the input clock, whereas the complementary signal (i_{P}) and (i_{N}) are again inverted through the main stage inverters, and the cross-coupled delay stage inverters improve the duty cycle of the inverted signal by 50%. Generally, the cross-coupled delay stages are marginally weaker than the main inverter to prevent the output from latching to either ‘high’ or ‘low.’ The cross-couple stage imparts additional delay to the cell, ensuring that each stage provides more than a 90-degree phase shift across the frequency range. The signal waveforms at terminals (A and B) also have a 180-degree phase shift. The delay compensation circuit again inverts the signal coming from (A and B) terminal at generates output waveform (op and on) which also has 180-degree phase shift.

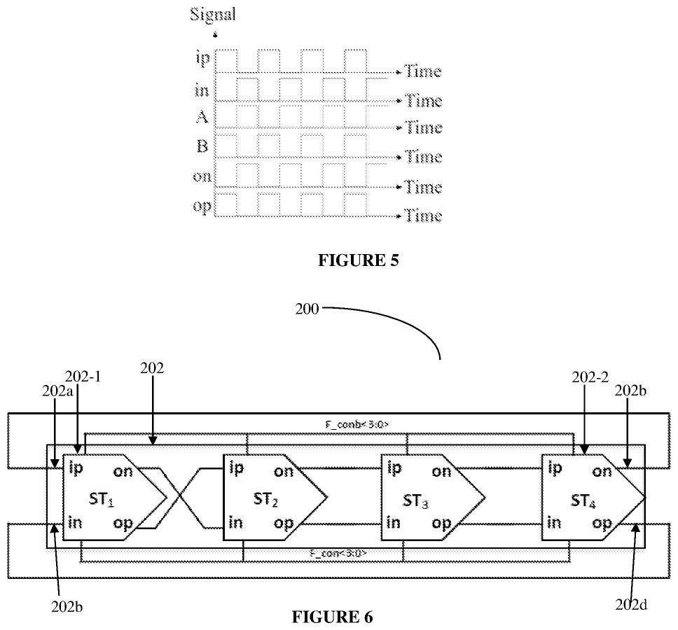

Now referring to FIG. 6 illustrates a 4-stage ring oscillator in accordance with an exemplary embodiment of the present disclosure. The 4-stage ring oscillator 200 is further configured to be integrated with a delay cell 100. The 4-stage ring oscillator 200 may further includes extra pins dedicated to control strength of a T-gate 106 provided within the delay cell 100. The addition of control bits enables adjustment of the T-gate 106 strength, thereby offering a means to optimize the supply sensitivity of the 4-stage ring oscillator 200.

In accordance with the exemplary embodiment, the supply sensitivity refers to the change in oscillation frequency per unit change in the power supply voltage and is measured in MHz per millivolt (MHz/mV). The supply sensitivity usually falls within a range of 50 to 100 MHz/mV. Further the range of 50 to 100 MHz/mV sensitivity is a critical parameter as it affects the stability and reliability of the oscillator's 200 operation. High supply sensitivity leads to significant fluctuations in oscillation frequency due to variations in the power supply voltage, affecting negatively the performance of the oscillator.

The 4-stage ring oscillator 200 may be configured to comprise a plurality of stages 202. Each stage from the plurality of stages 202 is configured to maintain the signal integrity of the supply sensitivity. Further each stage from the plurality of stages 202 is cross-coupled with next or adjacent stage. A compensation circuitry 104 provided within the delay cell 100 is positioned between a first stage 202-1 and a last stage 202-2 from the plurality of stages 202. The compensation circuitry 104 is configured to balance the resistance values in the oscillator circuit 200 in such a way that it improves the oscillator's performance without compromising its stability.

In another aspect of the exemplary embodiment, a first input 202a at the first stage 202-1 is connected with a first transmission gate (T-gate) 106a from the at least two transmission gate (T-gate) 106 provided with the compensation circuitry 104. Further a second input 202b at the first stage 202-1 is connected with a second transmission gate (T-gate) 106b from the at least two transmission gate (T-gate) 106.

Further in accordance with the aspect, a first output 202c at the last stage 202-2 is connected with the first transmission gate (T-gate) 106a. A second output 202d provided at the last stage 202-2 is connected with the second transmission gate (T-gate) 106b.

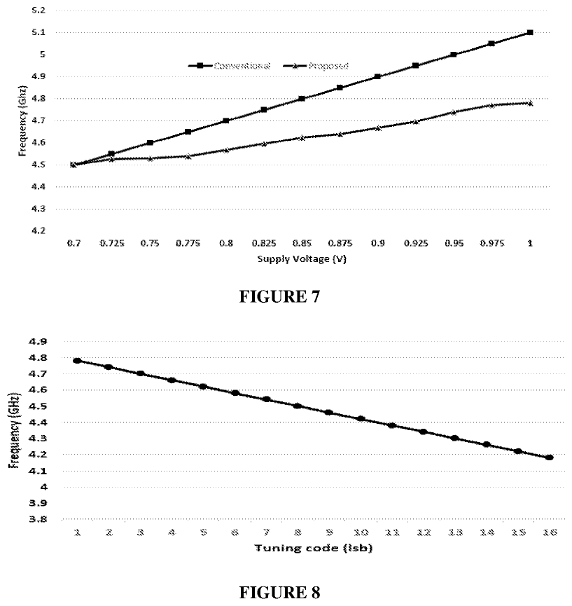

Referring to FIG. 7, illustrates a simulation comparison of supply sensitivity in accordance with an exemplary embodiment. The conventional approach exhibits a sensitivity of 52 MHz/mV under typical process conditions at room temperature. In contrast, the improved delay cell with supply sensitive oscillator significantly enhances sensitivity, achieving 21 MHz/mV, marking a substantial 50% improvement. This advancement offers the benefit of relaxing regulator specifications regarding required decapacitor quantity and bandwidth. Across the supply range of 700 mV to IV, the conventional VCO experiences a frequency drift of 600 MHz, while the proposed technique reduces this drift to 281 MHz.

Further referring to FIG. 8 illustrates a frequency sensitivity for ring oscillator 200 in accordance with the exemplary embodiment. The improved voltage controller oscillator (VCO)/4 stage ring oscillator 200/supply-sensitive ring oscillator is sensitive to control bits (F_con<3:0>). These bits enable tuning the 4 stage ring oscillator 200 frequency during startup. Notably, the improved supply sensitivity achieved by this innovation contributes to mitigating supply-induced spurs in the frequency domain and deterministic jitter in the time domain. Ultimately, this invention elevates clock quality without necessitating additional silicon area or increasing power consumption.

In some embodiments, the ring oscillator circuit comprises four inverters, at least two transmission gates (T-gate), and two resistors (Rc) to improve the supply sensitivity.

In some embodiments, the ring oscillator improves the supply sensitivity to mitigate supply-induced spurs in the frequency domain and deterministic jitter in the time domain.

In some embodiments, the ring oscillator improves clock quality without necessitating additional silicon area or increasing power consumption.

In some embodiments, the proposed ring oscillator optimizes the required supply sensitivity by balancing the resistance values (Rc) to enhance the performance of the ring oscillator without compromising the stability of oscillations.

In some embodiments, the ring oscillator minimizes the intrinsic supply sensitivity of the Voltage-Controlled Oscillator (VCO) by eliminating the need for external low-noise regulators and thereby reducing power and area overhead.

In some embodiments, the ring oscillator enhances the performance of phase-locked loop (PLLs) in clocked systems without compromising/degrading/decreasing supply robustness.

In some embodiments, the ring oscillator enhances sensitivity to 21 MHz/mV, by marking a substantial 50% improvement.

In some embodiments, the ring oscillator reduces the frequency drift up to 281 MHz.

With respect to the use of substantially any plural and/or singular terms herein, those having skill in the art can translate from the plural to the singular and/or from the singular to the plural as is appropriate to the context and/or application. The various singular/plural permutations may be expressly set forth herein for the sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present.

Although implementations for the ring oscillator have been described in language specific to structural features and/or methods, it is to be understood that the appended claims are not necessarily limited to the specific features described. Rather, the specific features are disclosed as examples of implementation for the ring oscillator.

1. A Phase-Locked Loop (PLL), comprising:
a delay cell 100, wherein delay cell 100 comprises:
a main cell 102;
a delay compensation circuitry 104, wherein the delay compensation circuitry 104 is integrally connected with the main cell 102; and
a ring oscillator 200 connected with the delay circuit 100, wherein the ring oscillator 200 is configured to be supply sensitive and assisted with a resistor;
wherein the ring oscillator 200 is connected to the delay cell 102 via the delay compensation circuitry 104;
wherein the ring oscillator 200 comprises a plurality of stages 202, and wherein each stage from the plurality of stages 202 is cross-coupled with a next or an adjacent stage from the plurality of stages 202.

2. The phase-locked loop as claimed in claim 1, wherein the main cell 102 comprises a plurality of NOT Gate (Inverter).

3. The phase-locked loop as claimed in claim 1, wherein the compensation circuitry 104 comprises at least two transmission gate (T-gate) 106a, 106b.

4. The phase-locked loop as claimed in claim 3, wherein, the at least two transmission gate (T-gate) 106 are configured to have unequal strengths for P and N transistors.

5. The phase-locked loop as claimed in claim 3, wherein the compensation circuitry 104 having the at least two transmission gate (T-gate) 106 is configured to adjust the size of the T-gate 106 through a 4-bit code (F_con<3:0>).

6. The phase-locked loop as claimed in claim 1, wherein the compensation circuitry 104 comprises at least two poly resistor 108, wherein each of the poly resistor 108 from the at least two poly resistor 108 is connected to each of the transmission gate (T-gate) 106a, 106b from the at least two transmission gate (T-gate) 106.

7. The phase-locked loop as claimed in claim 6, wherein the at least two poly resistor 108 have a fixed resistance value of R=3.4 kΩ.

8. The phase-locked loop as claimed in claim 1, wherein the compensation circuitry 104 is provided within the delay cell 100 and is positioned between a first stage 202-1 and a last stage 202-2 from the plurality of stages 202.

9. The phase-locked loop as claimed in claim 8, wherein a first input 202a at the first stage 202-1 is connected with a first transmission gate (T-gate) 106a and a second input 202b at the first stage 202-1 is connected with a second transmission gate (T-gate) 106b.

10. The phase-locked loop as claimed in claim 8, wherein a first output 202c at the last stage 202-2 is connected with the first transmission gate (T-gate) 106a and a second output 202d provided at the last stage 202-2 is connected with the second transmission gate (T-gate) 106b.
